(19) United States
(12) Patent Application Publication
(10) Pub. No.: US 2008/0190355 A1
(43) Pub. Date: Aug. 14, 2008

(54) Low-Doped Semi-Insulating Sic Crystals and Method

(75) Inventors: Jihong Chen, Saxonburg, PA (US); Ilya Zwieback, Township of Washington, NJ (US); Avinash K. Gupta, Basking Ridge, NJ (US); Donovan L. Barrett, Port Orange, FL (US); Richard H. Hopkins, Murrysville, PA (US); Edward Semenas, Rilnvill, NJ (US); Thomas A. Anderson, Convent Station, NJ (US); Andrew E. Souzis, Hawthorne, NJ (US)

Correspondence Address: THE WEBB LAW FIRM, P.C., 700 KOPPERS BUILDING, 436 SEVENTH AVENUE, PITTSBURGH, PA, 15219, US

(73) Assignee: II-VI INCORPORATED, SAXONBURG, PA (US)

(21) Appl. No.: 11/629,584

(22) PCT Filed: Jul. 6, 2005
(86) PCT No.: PCT/US2005/023796

§ 371 Date: Oct. 29, 2007

Related U.S. Application Data
(60) Provisional application No. 60/586,042, filed on Jul. 7, 2004.

(51) Int. Cl. C30B 33/02; H01B 1/02

(52) U.S. Cl. 117/3; 252/521.3; 252/520.4; 252/520.2

(57) ABSTRACT

The invention relates to substrates of semi-insulating silicon carbide used for semiconductor devices and a method for making the same. The substrates have a resistivity above 106 Ohm-cm, and preferably above 108 Ohm-cm, and most preferably above 109 Ohm-cm, and a capacitance below 5 pF/mm2 and preferably below 1 pF/mm2. The electrical properties of the substrates are controlled by a small amount of added deep level impurity, large enough in concentration to dominate the electrical behavior, but small enough to avoid structural defects. The substrates have concentrations of unintentional background impurities, including shallow donors and acceptors, purposely reduced to below 5·1016 cm−3, and preferably to below 1·1016 cm−3, and the concentration of deep level impurity is higher, and preferably at least two times higher, than the difference between the concentrations of shallow acceptors and shallow donors. The deep level impurity comprises one of selected metals from the periodic groups IB, IIB, IIIB, IVB, VB, VIB, VIIB and VIIIB. Vanadium is a preferred deep level element. In addition to controlling the resistivity and capacitance, a further advantage of the invention is an increase in electrical uniformity over the entire crystal and reduction in the density of crystal defects.

### BACKGROUND OF THE INVENTION

1. Field of the Invention

The present invention relates to the creation of semi-insulating SiC material, and the growth of high quality crystals of this material to produce substrates that are useful for RF, microwave and other device applications.

2. Description of the Prior Art

Silicon carbide (SiC) is a wide bandgap semiconductor material with a unique combination of electrical and thermo-physical properties that make it extremely attractive and useful for the new generation of electronic devices. These properties include high breakdown field strength, high practical operating temperature, high electron saturation velocities, high thermal conductivity and radiation hardness. These properties make possible device operation at a significantly higher power, higher temperature and with more radiation resistance than comparable devices made from the more conventional semiconductors such as Si and GaAs (D. L. Barrett et al., J. Crystal Growth, v. 109, 1991, pp. 17-23). It is estimated that transistors fabricated from high resistivity “semi-insulating” SiC are capable of producing over five times the power density of comparable GaAs microwave components at frequencies up to 10 GHz. (U.S. Pat. No. 5,611,955; see also S. Sriram et al., IEEE Elect. Dev. Letters, v. 15, 1994, pp. 458-459; S. T. Allen et al., Proc. Int'l Conf. on SiC, 1995, Inst. of Physics). Semi-insulating SiC is also a preferred substrate for the growth of GaN-based epitaxial structures, which can be fabricated into microwave transistors and circuits operational at even higher frequencies and power loads than SiC-based devices (see for example J. L. Pancove, Mater. Sci and Engr. v. B61-62, 1999, pp. 305-309).

To provide optimum microwave device performance, the SiC substrates from which devices are made must be “semi-insulating”, that is they must exhibit an appropriately high and spatially uniform resistivity combined with low capacitance. In addition, the substrates must have low densities of structural defects and have high thermal conductivity.

Those familiar with microwave device technology recognize that SiC substrate resistivity is crucial to successful device applications. For example, it is calculated that a 1500 Ohm-cm resistivity represents a minimum value to achieve RF passive behavior. Resistivities above 5000 Ohm-cm are needed to minimize device transmission line losses to below 0.1 dB/cm. To minimize device back-gating and to achieve the device isolation needed for integrated circuit fabrication, the resistivity should exceed 50,000 Ohm-cm (U.S. Pat. No. 5,611,955; U.S. Pat. No. 6,396,080; and U.S. Pat. No. 6,218,680).

The substrate capacitance represents a parasitic capacitance of the device, which causes a series of undesirable effects ranging from lowering power efficiency to distortions in the frequency response. Device designers and manufacturers currently specify SiC substrates with a capacitance below 5 pF/mm², and often request values as low as 1 pF/mm².

High thermal conductivity represents another crucial requirement to the substrate. This is needed to facilitate the dissipation of heat released in the device structure. In order to have a high thermal conductivity, the substrate must demonstrate high crystallographic quality with minimal densities of structural defects and a low concentration of impurities.

In brief, the use of high resistivity and high crystal quality semi-insulating SiC substrates enables the fabrication of high performance microwave devices and creates the opportunity for a wide range of product applications from communications devices such as cell phones to powerful air and ship-borne radars.

The main approaches that have been used to create the required semi-insulating behavior in SiC crystals are: (1) formation of deep levels within the SiC bandgap to compensate residual shallow impurities by doping with selected metals, especially vanadium (U.S. Pat. No. 5,611,955); (2) use of deep levels associated with native point defects to compensate residual shallow impurities (U.S. Pat. Nos. 6,218,680 and 6,396,080; see also St. G. Mueller, Mat Sci. Forum, V. 389-393 (2002) pp. 23-28); and (3) compensation of residual shallow impurities by a combination of the deep level impurity doping with the use of native point defects (Patent Application Publication No. 2003/0079676 A1). Other useful references describing semi-insulating SiC technology include: H. M. Hobgood et al., Appl. Phys. Lett., 66 (1995), p. 1364; A. O. Evwareye et al., J. Appl. Phys, 76 (1994) pp. 5769-5762; and J. Schneider et al., Appl. Physics Letters, 56 (1990) pp. 1184-1186.

As described below, each of the current approaches used to create semi-insulating behavior in SiC exhibits disadvantages that limit the ability of the SiC substrate to meet all of the critical characteristics desired for the microwave device fabrication.

The essence of the first approach is the introduction of a metal, such as vanadium, in the SiC crystal lattice as a compensating dopant. The introduction of vanadium, as described in U.S. Pat. No. 5,611,955, is recognized as a conventional technique for the production of semi-insulating SiC. The teachings of this reference instruct on neither the requirements to the purity of raw materials and/or growth process, nor the specific amount of the dopant added. It is required only that the concentration of deep levels produced by the dopant in the crystal be higher than the levels of unintentionally present background shallow impurities, such as boron and nitrogen.

As those skilled in the art recognize, B and N can often be present in SiC crystals conventionally grown by sublimation to be in excess of 5·10¹⁶ cm⁻³, and up to 7·10¹⁷ cm⁻³, depending on the materials used in the growth process (H. M. Hobgood et al., Appl. Phys. Lett. 66 (11), p. 1364 (1995), R. C. Glass, Proc. Int'l. Conf. on SiC, 1995, Inst. of Physics). According to the teachings in the references, in order to achieve reliable compensation and high resistivity, the concentration of the dopant (vanadium) must be higher than those numbers and, therefore, be close to the limit of vanadium solubility in SiC, which is about 5·10¹⁷ cm⁻³. It is also recognized that heavy doping with vanadium, with its concentration being close to or in excess of the solubility limit, will have a negative impact on crystal properties (see for example U.S. Pat. No. 6,218,680 and U.S. Pat. No. 6,396,080). Some of the negative consequences of heavy doping with vanadium are: (a) the large amount of dopant needed to compensate typical SiC crystals can severely impair electronic behavior; (b) the control of resistivity and capacitance at high doping concentrations is technically complicated and can produce variable material yield and higher process cost; (c) at high concentrations, only a fraction of the dopant atoms is electrically active, with the remainder forming “clouds” and clusters around dislocations and micropipes (see M. Bickermann et al., J. Crystal Growth, 254 (2003) pp. 390-399); such non-uniform distribution of the dopant leads to stress and generation of additional defects and subsequently reduced device yield; and (d) high concentrations of compensating elements and defects caused by heavy doping will reduce substrate thermal conductivity and therefore limit device output power. When present in high concentrations in the substrate, vanadium can cause unwanted trapping, p-n junction pinching and back-gating in the epitaxial device structure.

Both the second approach and the third approach propose the use of native point defects having deep levels in the bandgap for the compensation of SiC. An additional feature of the third approach is a combination of deep level doping (e.g., with titanium) with the use of native point defects. This third approach apparently combines the teachings of U.S. Pat. No. 5,611,955; U.S. Pat. No. 6,218,680; and U.S. Pat. No. 6,396,080 with the process feature that the SiC crystals are grown by a high temperature chemical vapor deposition process (HTCVD) rather than by the more conventional physical vapor transport process (PVT).

As it is apparent to those familiar with fundamental properties of SiC and skilled in the art of SiC crystal growth, the chemistry of native point defects in SiC is not well understood. Studies of photoluminescence, Hall effect, DLTS and EPR carried out during the recent decade have established a number of possible point defects in SiC. These include silicon vacancy, carbon vacancy, silicon-on-carbon anti-site, and defects of unknown nature called conventionally UD1, UD2 and UD3. Some of these defects can have their energy levels deep in the SiC bandgap; therefore, they can be potentially used for electronic compensation (A. Ellison et al., Mat. Sci. Forum, 433-436 (2003) pp. 33-38).

It is widely recognized that larger quantities of point defects can be introduced by nuclear irradiation of a crystal with fast electrons, neutrons and y-rays. However, the radiation damage defects are unstable, and rapidly anneal out at elevated temperatures via secondary reactions with pre-existing defects and impurities, self-annihilation and clustering.

In brief, the second and the third approaches require that the growth of SiC crystals is carried out in a manner that ensures a combination of extremely low levels of background shallow impurities and with a sufficient number of deep intrinsic defects in order to achieve a desired degree of compensation. Those skilled in the art of SiC crystal growth would immediately recognize the practical disadvantages stemming from the reliance on the native point defects. These disadvantages include: (1) the nature of native point defects in SiC crystals and their effect on creating semi-insulating behavior is unclear; (2) the nature of high-temperature thermochemistry of SiC makes proactive control of intrinsic point defects difficult to achieve in practice, and leads to manufacturing complexity and high production cost; (3) intrinsic defects, including growth-induced and those introduced by irradiation, are often unstable and anneal over time; in addition, some of the radiation-induced defects can be harmful for the substrate properties; (4) extremely low concentrations of unintentional background impurities, with boron and nitrogen at levels of 10¹⁵ cm⁻³ or below, are required in order for the native point defects with deep levels to become dominant and cause a high degree of compensation; this requirement is very difficult to fulfill in practice; and (5) specific measures taught in the second approach (U.S. Pat. Nos. 6,218,680 and 6,396,080) aimed at achieving an extremely high degree of crystal purity, such as large source-to-seed temperature differences (300-350° C.), and higher than usual growth temperatures, can compromise compositional uniformity of the crystal and facilitate crystal defect formation (carbon inclusions, micropipes, secondary grains, etc.).

The third approach (U.S. Patent Application Publication No. 2003/0079676 A1) contains further disadvantages. It requires simultaneous control over the amounts of shallow impurities, native point defects and the deep metal impurities. This is extremely difficult to achieve in practice and leads to process complexity, low substrate yields and high cost. In addition, it requires the use of the HTCVD crystal growth process, which is industrially more complex and expensive than conventional PVT.

### SUMMARY OF THE INVENTION

The invention disclosed herein is a direct method for forming semi-insulating SiC which overcomes the main disadvantages of the three prior art approaches discussed above. The invention represents a significant improvement over the teachings and drawbacks of U.S. Pat. No. 5,611,955 by providing: (1) SiC single crystal with a controlled concentration of metal doping introduced in quantities sufficient to dominate the electrical behavior of the SiC substrate, but small enough to avoid the formation of precipitates and other structural defects; (2) SiC single crystal with a concentration of metal doping which is higher, and preferably at least two times higher, than the shallow impurity concentration; (3) SiC single crystal with background concentrations of two main shallow impurities, boron and nitrogen, below 5·10¹⁶ cm⁻³ and preferably below 1·10¹⁶ cm⁻³ with the concentration of residual boron preferably exceeding that of nitrogen; and (4) SiC single crystal with low concentrations of other background impurity elements, including aluminum and transition metals, preferably below 5·10¹⁴ cm⁻³ each.

This unique combination of characteristics overcomes the deleterious non-uniformity in resistivity, high capacitance, and low thermal conductivity, resulting in low substrate yields that are common to the previous art of semi-insulating SiC production methods. In this invention, the complexities such as control over intrinsic point defects and in their deliberate introduction, or use of a complex HTCVD technique, are not required. In the preferred embodiment of this invention, semi-insulating behavior with high and uniform substrate resistivity is achieved using conventional PVT growth technique with a small, defect-avoiding amount of compensating metal (vanadium) and sufficiently low background impurity concentrations.

An objective of this invention is to provide semi-insulating silicon carbide substrates with high resistivity, low capacitance, uniform electrical properties and structural quality suitable for the production of high power, high frequency devices, while avoiding the problems and difficulties of prior art. The invention meets this objective with a semi-insulating SiC substrate having: (a) a resistivity of at least 10⁶ Ohm-cm at room temperature and preferably above 10⁸ Ohm-cm and most preferably above 10⁹ Ohm-cm, and capacitance of below 5 pF/mm and preferably below 1 pF/mm²; (b) concentrations of shallow impurities (boron and nitrogen) of less than 5·10¹⁶ cm⁻³, and preferably below 1·10¹⁶ cm⁻³ with the concentration of boron preferably exceeding that of nitrogen; (c) concentrations of other unintentional background impurities, such as aluminum and transition metals, are below 1·10¹⁵ cm⁻³, and preferably below 5·10¹⁴ cm⁻³; and (d) concentrations of a deep trapping dopant in excess of the net shallow impurity concentration and preferably at least twice as high as the net shallow impurity concentration, making the said deep trapping impurity dominant to control the electrical properties of the substrate. Vanadium is a preferred deep level metallic dopant.

In another aspect of the invention, the vapor transport growth technique used to produce semi-insulating SiC crystals is characterized by: (a) the preparation and use of a silicon carbide source material, wherein the concentration of unintentional background contaminants is low and preferably below the detection limit of ordinary analytical means such as Glow Discharge Mass Spectroscopy (GDMS), particularly, boron in the source is below 2·10¹⁵ cm⁻³; (b) the incorporation of a deep level compensating dopant within the source material in sufficient quantity to compensate any residual shallow impurities in the final crystal; (c) the graphite parts of the sublimation growth furnace are highly purified by well-described techniques to contain low boron quantities, preferably of 0.05 weight ppm or below; (d) the sublimation growth is carried out to produce single polytype crystals of high purity and a low concentration of extrinsic deep levels exhibiting a high resistivity of at least 1·10⁶ Ohm-cm, preferably higher than 1·10⁸ Ohm-cm, and most preferably higher than 1·10⁹ Ohm-cm; (e) the substrates fabricated from a crystal exhibit a resistivity that is uniform to at least ±15% over the substrate area; and (f) the substrates fabricated from a crystal exhibit a capacitance of less than 5 pF/mm² and preferably less than 1 pF/mm².

### BRIEF DESCRIPTION OF THE DRAWINGS

FIG. 1 is a schematic diagram of a PVT growth assembly;

FIG. 2 is a graph showing the axial resistivity profile of 6H SiC crystal A4-261 with a mean resistivity of 1.79·10¹¹ Ohm-cm, and a standard deviation across the substrate area of ˜3.5%; and

FIG. 3 is a graph showing the axial resistivity profile of 6H SiC crystal A4-270 with a mean resistivity of 3·10¹¹ Ohm-cm.

### DETAILED DESCRIPTION OF THE PREFERRED EMBODIMENTS

In a first embodiment, the present invention is a semi-insulating SiC single crystal having only one purposely added deep level dopant. The improvement is a semi-insulating SiC single crystal having concentration of deep level element that is less than required by prior art and that is substantially below the solubility limit of the selected element in SiC. The improvement is a semi-insulating SiC single crystal having a concentration of the deep level element higher than the net shallow impurity concentration and, preferably, twice as much as the net shallow impurity concentration. The improvement is a semi-insulating SiC single crystal having a concentration of shallow impurities below 5·10¹⁶ cm⁻³, and preferably below 1·10¹⁶ cm⁻³, with the concentration of shallow donors preferably lower than that of shallow acceptors. The improvement is a semi-insulating SiC single crystal having concentrations of other background impurities below 10·15 cm⁻³ and preferably below 5·10¹⁴ cm⁻³. Vanadium is a preferred deep level element for this invention.

As used herein, the term “shallow impurity element” refers to those elements in the periodic table which, when incorporated in the SiC lattice, form states with their energy levels between the valence and conduction band edges of SiC that are removed from the band edges by 0.3 eV or less.

Boron and nitrogen are the shallow background impurities that can dramatically reduce the resistivity and that are most difficult to remove from SiC. Boron is a shallow acceptor with energy levels 0.3 eV above the valence band edge. Nitrogen is a shallow donor with its level about 0.1 eV below the conduction band edge. Accordingly, the improvement disclosed here is semi-insulating SiC single crystal having concentration of both boron and nitrogen reduced to below 5·10¹⁶ cm⁻³ and preferably below 1·10¹⁶ cm⁻³.

When nitrogen is present in a SiC crystal in a concentration below that of boron, a smaller concentration of the deep level dopant is required to achieve deep compensation and high resistivity than when nitrogen dominates over boron. Accordingly, the improvement disclosed here is semi-insulating SiC single crystal having nitrogen concentration preferably below that of boron.

As used herein, the term “net shallow impurity concentration” refers to the difference between concentrations of shallow acceptors (boron, aluminum) and shallow donors (nitrogen, phosphorus). The higher the net shallow impurity concentration, the higher the deep dopant concentration required for the compensation. Accordingly, the improvement disclosed here is semi-insulating SiC single crystal having a low net shallow impurity concentration.

As used herein, the term “background impurity” refers to those elements in the periodic table that are unintentionally present in the SiC crystal lattice. Examples of background impurities in SiC include, in addition to boron and nitrogen, aluminum and transition metals. The presence of background impurities can cause reduction in the crystal resistivity. Accordingly, the improvement disclosed here is semi-insulating SiC single crystal having concentrations of background impurities, other than boron and nitrogen, reduced to very low levels, preferably below 5·10¹⁴ cm⁻³.

As used herein, the term “deep level element” refers to those elements in the periodic table which, when incorporated in the SiC lattice, form states at energy levels between the valence and conduction band edges of SiC that are removed from the band edges by 0.3 eV or more. Doping with deep level elements is commonly used to achieve compensation and high resistivity in the semiconductor.

, Specifically, the deep level impurity comprises one of selected metals, the selected metal being a metal found in the periodic groups IB, IIB, IIIB, IVB, VB, VIB, VIIB and VIIIB. Commonly recognized deep level elements in SiC are vanadium and titanium. Although the basic concept of deep level doping for semi-insulating behavior is described below using vanadium as a preferred example, it will be recognized that this invention is not limited to the selection of vanadium as a deep level element As those familiar with the art recognize, the deep level-element vanadium, when incorporated in the SiC crystal lattice, forms two deep levels in the bandgap: one acceptor at about 0.66 eV-0.8 eV below the conduction band and one donor at 1.5 eV above the valence band.

When the concentration of the deep level element present in the SiC crystal is below that of the net shallow impurity, the result is insufficient compensation and low resistivity. Accordingly, the improvement disclosed here is semi-insulating SiC single crystal having the deep level element (vanadium) in a concentration that is higher than the net shallow impurity concentration and preferably twice as much as the net shallow impurity concentration.

As used herein, the term “precipitates” refers to harmful secondary phases formed inside the SiC crystal when an impurity is present in a concentration exceeding its solubility in SiC. Accordingly, the improvement disclosed here is a semi-insulating SiC single crystal having a concentration of deep level dopant (vanadium) substantially below its local solubility limit in a crystal and in quantities that do not cause generation of precipitates and other structural defects.

The semi-insulating SiC crystals must have the highest possible resistivity, at least 10⁵ Ohm-cm at room temperature. Semi-insulating SiC substrates grown according to the previous art demonstrate their resistivity between 10⁵ and 10⁶ Ohm-cm. Accordingly, the improvement is a semi-insulating SiC single crystal having a resistivity of at least 10⁶ Ohm-cm and preferably 10⁸ Ohm-cm or higher and most preferably 10⁹ Ohm-cm or higher. Additionally, the improvement is a semi-insulating SiC single crystal having a resistivity with uniformity of at least +15% across the substrate area.

The semi-insulating SiC crystals must have the lowest possible capacitance. Semi-insulating SiC substrates grown according to the prior art demonstrate their capacitance between 5 pF/mm² and 20 pF/mm². Accordingly, the improvement is a semi-insulating SiC single crystal having a capacitance below 5 pF/mm² and preferably below 1 pF/mm².

The semi-insulating SiC crystals must have a high thermal conductivity. Semi-insulating SiC substrates grown according to the prior art and containing high concentrations of background impurities and deep level dopant (vanadium) demonstrate their thermal conductivity between 300 and 350 W/m-K. Accordingly, the improvement is expected to be a semi-insulating SiC single crystal having a thermal conductivity at least 320 W/m-K, and preferably above 350 W/m-K, and most preferably above 400 W/m-K.

Although other SiC polytypes are possible, the silicon carbide single crystal of the present invention preferably has a polytype of 6H, 4H, 3C or 15R.

In another embodiment, the invention comprises a method of producing semi-insulating silicon carbide bulk single crystal. In this embodiment, the method comprises subliming a SiC source material and re-condensing it onto a single crystal seed through a preset temperature gradient between the seed and the source. The method can be characterized by the following distinctive features: 1) background contamination of the final crystal stemming from the source is minimized; in particular, the amounts of impurities in the synthesized ultra-high purity SiC source material are below their GDMS detection limits; boron, specifically, is below 2·10¹⁵ cm⁻³; 2) background contamination of the final crystal by boron is minimized; in particular, high purity graphite parts with low boron content are used as hot zone elements and crucibles, preferably containing below 0.05 weight ppm of boron; 3) background contamination of the final crystal by nitrogen is minimized; in particular, growth of SiC crystal is carried out at a sufficiently high temperature and under reduced pressure to minimize nitrogen incorporation and to make it preferably below that of boron; 4) the claimed method produces deep electrical compensation of the final crystal; in particular, a pre-determined amount of deep level dopant, preferably elemental vanadium or vanadium compound such as vanadium carbide, is added to the ultra-high purity SiC source material; the dopant is added in carefully controlled quantities sufficient to achieve the concentration of deep level element (vanadium) that is higher than the shallow impurity concentration and preferably at least twice as much as the shallow impurity concentration in the crystal; and 5) special measures are taken to avoid generation of precipitates and other structural defects in the crystal; in particular, the amount of deep level metal (i.e., vanadium) added to the source is such that the dopant concentration in the crystal is substantially below its solubility limit.

In addition, the temperature difference between seed and source during sublimation growth is closely controlled. The temperature is established just high enough for efficient vapor transport from source to seed but low enough to prevent stress, cracks, micropipes and other structural defects.

### EXAMPLES

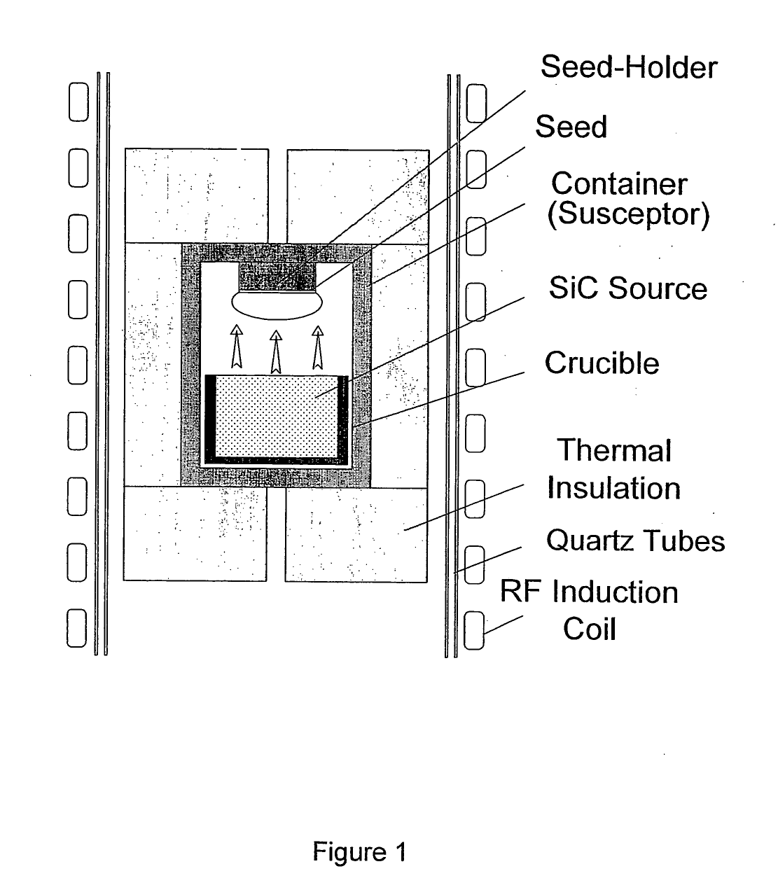

In accordance with the present invention, vanadium doped semi-insulating single crystals of 6H SiC with high resistivity, low capacitance and high thermal conductivity are produced using a Physical Vapor Transport (PVT) growth technique. A schematic diagram of the PVT growth assembly is given in FIG. 1. The growth container and other components of the hot zone are made of dense graphite and purified using well-described industrial procedures in order to reduce the boron content, preferably to 0.05 weight ppm or below. Typical impurity content in low-boron graphite is shown in Table 1.

TABLE 1
Purity of graphite used in SiC crystal growth, GDMS, wppm.

| B | Na | Al | Si | S | Cl | Ti | V | Fe | Ni |
|---|---|---|---|---|---|---|---|---|---|
| 0.03 | <0.01 | <0.05 | 0.16 | 0.66 | <0.05 | <0.01 | <0.005 | <0.01 | <0.01 |

High-purity polycrystalline SiC is synthesized in a separate procedure and is used as a source in the PVT growth process. The metallic impurities in the SiC source powder as measured by GDMS are below their GDMS detection limits, including boron below 2-10¹⁵ cm⁻³, as shown in Table 2.

TABLE 2
Purity of synthesized polycrystalline SiC source, GDMS, cm⁻³.

| B | Al | Ti | V | Cr | Fe | Ni |
|---|---|---|---|---|---|---|
| <1.81 · 10¹⁵ | <7.25 · 10¹⁴ | <4.08 · 10¹⁴ | <3.84 · 10¹⁴ | <3.76 · 10¹⁵ | <1.75 · 10¹⁵ | <3.33 · 10¹⁴ |

In order to achieve the desired degree of compensation by vanadium, a proper amount of elemental vanadium, vanadium carbide, or other V-bearing species is added to the SiC source and/or to the growth atmosphere.

A seed mounted on the seed-holder and the high-purity polycrystalline SiC source are loaded into the container, and the latter is placed inside the growth chamber, as shown in FIG. 1. In order to minimize contamination by nitrogen, loading and positioning of the container inside the growth chamber is carried out under flow of pure inert gas.

As a first step of the process, the growth chamber with the container is evacuated and held under vacuum to remove air trapped in graphite. Following this, the chamber is filled with inert gas (argon or helium) under a preferred pressure below one atmosphere, and the temperature is raised to a preferred value.

The container serves as a susceptor and couples energy from an induction coil positioned coaxially around the chamber. At the beginning of the growth cycle, the axial position of the coil is adjusted to achieve the preferred temperatures at the container top and bottom, as measured by a pyrometer.

Practical examples of the invention are described below.

### Example 1

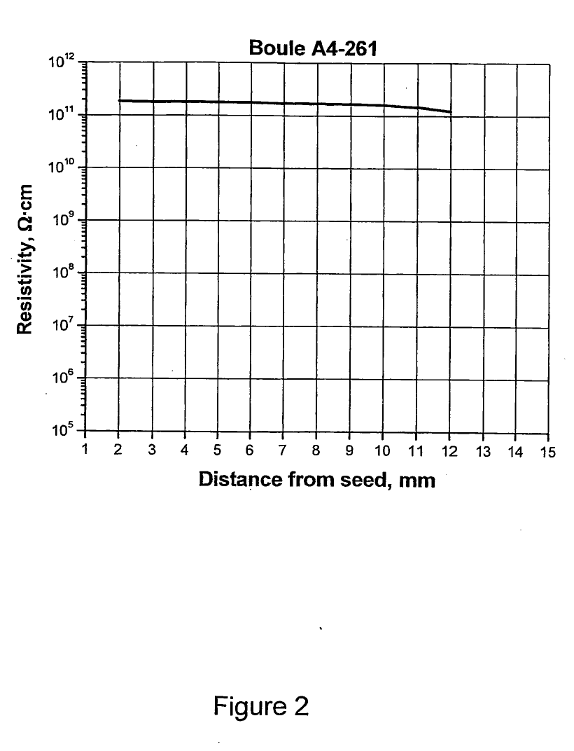

A 2-inch diameter vanadium-doped semi-insulating SiC crystal (boule A4-261) was grown at a seed temperature of 2050° C. and source temperature of 2100° C. The growth ambient was 10 torr of helium. The resulting crystal exhibited a very high and uniform resistivity above 10¹¹ Ohm-cm, as illustrated in FIG. 2, with the standard deviation in resistivity across the substrate areas of about 3.5%. The substrate capacitance measured by a mercury probe at 10 kHz was below 0.2 pF/mm².

The impurity content of crystal A4-261 was analyzed using Secondary Ion Mass Spectroscopy (SIMS). The results are shown in Table 3.

TABLE 3
Impurity content in SI SiC crystal A4-261, cm⁻³.

| B | N | V | Al | Ti |
|---|---|---|---|---|
| 2.3 · 10¹⁶ | 4.9 · 10¹⁶ | 6.0 · 10¹⁶ | 3.0 · 10¹⁴ | 4.0 · 10¹⁴ |

The vanadium content is nearly an order of magnitude lower than its solubility in SiC, but at the same time it is roughly two times higher than the net shallow impurity concentration (nitrogen minus boron). In this case, the nitrogen concentration was higher than that of boron, but the degree of compensation by vanadium was sufficient to attain a high resistivity, semi-insulating behavior.

The relatively low concentration of vanadium compared to the prior art (where it is as high as 4·10¹⁷ cm⁻³) did not cause any precipitates as evaluated by high magnification optical microscopy. There was also no increase in the micropipe density, compared to crystals grown in similar conditions without intentional doping. Finally, as it follows from Table 3, the concentrations of background A1 and Ti are below 5·10¹⁴ cm⁻³.

### Example 2

A 2-inch diameter vanadium-doped semi-insulating SiC crystal (boule A1-367) was grown in conditions similar to those of Example 1 (boule A4-261), except special measures were taken during growth in order to minimize the content of residual nitrogen in the crystal and make it below that of boron.

The impurity content of boule A4-367 has been analyzed using SIMS, and the results are shown in Table 4.

TABLE 4
Impurity content in SI SiC crystal Al-367, cm⁻³.

| B | N | V | Al | Ti |
|---|---|---|---|---|
| 4.3 · 10¹⁶ | 9 · 10¹⁵ | 5.3 · 10¹⁶ | 3.0 · 10¹⁴ | 2.0 · 10¹⁴ |

The SIMS data demonstrates the nitrogen content is reduced to a level below that of boron. One can also see that, similar to Example 1, the vanadium content is substantially lower than its solubility limit and it is sufficiently higher than the net shallow impurity concentration (boron minus nitrogen) to achieve semi-insulating behavior, as described below.

A combination of sufficient vanadium doping with a relatively low level of nitrogen resulted in an extremely high crystal resistivity. In fact, the resistivity was higher than the upper sensitivity limit of the non-contact resistivity meter (COREMA), which is about 3·10¹¹ Ohm-cm. The capacitance of substrates sliced from boule A1-367, as measured by the mercury probe at 10 kHz, was below 0.1 pF/mm². No vanadium precipitates or any other defects related to vanadium doping were found in this crystal.

### Example 3

A 2-inch diameter vanadium-doped semi-insulating SiC crystal (boule A4-270) was grown in conditions similar to those described above. Similar to Example 2, special measures were taken during growth to minimize the nitrogen background contamination.

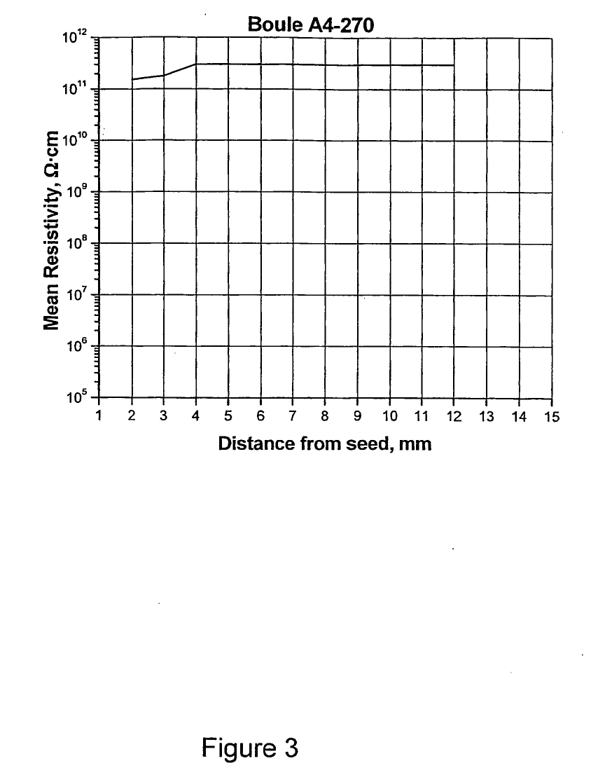

The axial distribution of resistivity in boule A4-270 shown in FIG. 3 demonstrates a very high and uniform resistivity, close to 3·10¹¹ Ohm-cm. The substrate capacitance was below 0.1 pF/mm².

The impurity content of crystal A4-270 is shown in Table 5.

TABLE 5
Impurity content in SI SiC crystal A4-270, cm⁻³.

| B | N | V | Al | Ti |
|---|---|---|---|---|
| 1.15 · 10¹⁶ | 8.1 · 10¹⁵ | 3.53 · 10¹⁶ | 3.0 · 10¹⁴ | 1.0 · 10¹⁴ |

The SIMS data demonstrates a level of nitrogen below that of boron and the vanadium concentration about four times higher than the net shallow impurity concentration (boron minus nitrogen). No vanadium precipitates or any other vanadium-related defects were present in the boule.

### Example 4

In this example, we present a comparison between the background impurity concentrations, deep level metal dopant concentration, resistivity, electrical uniformity, capacitance and defect densities of 6H SiC crystals grown in accordance with the invention, and with crystals grown according to U.S. Pat. No. 5,611,955, respectively.

The properties of vanadium-doped 6H SiC crystals grown using the teachings of U.S. Pat. No. 5,611,955 and crystals grown in accordance with the present invention are listed in Table 6.

TABLE 6
Comparison of SiC crystals grown according to U.S. Pat. No.
5,611,955 and those grown according to the present invention.

| Property | U.S. Pat. No. 5,611,955 | Present Invention |
|---|---|---|
| Background Nitrogen | 5 · 10¹⁶-3 · 10¹⁷ cm⁻³ | 6 · 10¹⁵-6 · 10¹⁶ cm⁻³ |
| Background Boron | 6 · 10¹⁶-1 · 10¹⁷ cm⁻³ | 5 · 10¹⁵-3 · 10¹⁶ cm⁻³ |
| Vanadium | 5 · 10¹⁶-4 · 10¹⁷ cm⁻³ | 1 · 10¹⁶-6 · 10¹⁶ cm⁻³ |
| Concentration | | |
| Resistivity (ρ) | 10⁴-10⁷ Ohm-cm | 10⁶-3 · 10¹² Ohm-cm |
| Uniformity of ρ across | ±60% | ±15% |
| wafer area | | |
| Capacitance | 5-80 pF/mm² | 0.1-5 pF/mm² |
| Vanadium precipitates | Frequent | None |
| Micropipe density | 20-100 cm⁻² | 5-20 cm⁻² |

As follows from this table, the present invention leads to a dramatic improvement in the electrical properties of semi-insulating SiC crystals, as well as in their uniformity and structural quality.

While preferred embodiments of the present invention were described herein, various modifications and alterations of the present invention may be made without departing from the spirit and scope of the present invention. The scope of the present invention is defined in the appended claims and equivalents thereto.

We claim:

1. A composition of matter for use in semiconducting devices, comprising a single polytype single crystal of silicon carbide, having a resistivity of at least 1·10⁶ Ohm-cm at room temperature, and having deep level dopants and low concentrations of background impurities therein; wherein the deep level dopants have their energy levels at a depth of at least 0.3 eV from the edge of the SiC bandgap; wherein the deep level dopant is an element found in the periodic groups IB, IIB, IIIB, IVB, VB, VIB, VIIB or VIIIB; wherein the concentration of the deep level dopant is below its solubility limit in SiC; wherein the concentrations of shallow impurities of boron and nitrogen of less than 5·10¹⁶ cm⁻³, and preferably below 1·10¹⁶ cm ⁻³; wherein the concentrations of other unintentional background impurities, such as aluminum and transition metals, are below 1·15 cm⁻³, and preferably below 5·10¹⁴ cm⁻³; wherein the concentration of the deep level dopant is greater than the difference between the concentrations of shallow acceptors and shallow donors, and preferably two times greater than the said difference; and wherein the concentration of shallow donors is smaller than the concentration of shallow acceptors.

2. The composition of matter of claim 1 wherein the deep level dopants are at least one of the elements found in periodic groups IB, IIB, IIIB, IVB, VB, VIB, VIIB and VIIIB or a combination of these elements.

3. The composition of matter of claim 1 wherein the selected deep level dopant is vanadium.

4. The composition of matter of claim 1 wherein the selected deep level dopant is titanium.

5. The composition of matter of claim 1 wherein the deep level dopant is incorporated during deposition of silicon carbide from a vapor phase.

6. The composition of matter of claim 1 wherein the silicon carbide polytype is one of 2H, 4H, 6H, 3C and 15R.

7. The composition of matter of claim 1 wherein the resistivity uniformity of fabricated substrates across the substrate area is within ±15%.

8. The composition of matter of claim 1 wherein the substrate capacitance is below 1 pF/mm².

9. The composition of matter of claim 1 wherein the thermal conductivity is above 320 W/m-K, preferably above 350 W/m-K, and most preferably above 400 W/m-K.

10. A composition of matter for use in semiconductor devices comprising a silicon carbide semiconductor material wherein the concentration of shallow dopants of energy levels from band-edge less than 0.3 eV is less than 1·10¹⁶ cm⁻³; wherein the deep level dopants include an element found in the periodic groups IB, IIB, IIIB, IVB, VB, VIB, VIIB or VIIIB; and wherein the concentration of deep level dopant is below 2·10¹⁶ cm⁻³.

11. The composition of matter of claim 10 produced from a specially prepared source material in which individual shallow donors nitrogen and phosphorus, and individual shallow acceptors aluminum and boron are at least less than 5·10¹⁶ cm⁻³, and preferably below the detection limit of ordinary GDMS measurement.

12. The composition of matter of claim 10 wherein the selected deep level dopant is present at concentrations less than 1·10¹⁶ cm³.

13. The composition of matter of claim 10 wherein the selected deep level dopant is vanadium present at concentrations less than 1·10¹⁶ cm⁻³.

14. The composition of matter of claim 10 wherein the dopant is incorporated during deposition of silicon carbide from a vapor phase.

15. A composition of matter for use in semiconductor devices comprising a silicon carbide semi-insulating crystal having a resistivity of greater than 1·10⁶ Ohm-cm, wherein the concentration of a deep level dopant having a depth of at least 0.3 eV is less than 1·10¹⁶ cm⁻³; wherein the concentration of a shallow level dopant having a depth of less than 0.3 eV is less than 1·10¹⁶ cm⁻³; and wherein the substrate capacitance is less than 1 pF/mm².

16. A method of producing a semi-insulating single crystal of silicon carbide, the method comprising the steps of:
heating a specially-purified silicon carbide source material containing a defined but small amount of deep level trapping element to sublimation while,
heating a silicon carbide seed crystal to a temperature less than that of the source at which temperature the sublimed silicon carbide and deep level species from the source will condense on the seed,
continuing to heat the source and seed until the desired amount of purposely-doped single crystal has grown upon the seed while,
maintaining the growth temperature and growth pressure in ranges that sustain the high purity environment and facilitate the incorporation of the deep level element in the crystal.

17. The method according to claim 16 wherein the silicon carbide source material contains the concentration of shallow impurities, particularly boron and nitrogen, below 1·10¹⁶ cm⁻³ and preferably below the detection limit of ordinary analytical means such as GDMS.

18. The method according to claim 16 wherein the source powder contains a deep level trapping element selected from one of the metal elements found in periodic groups IB, IIIB, IIIB, IVB, VB, VIB, VIIB and VIIIB.

19. The method according to claim 16 wherein the concentration of the deep level trapping element in the source powder is chosen in sufficient quantity to compensate any residual carriers in the final crystal and to be below the solubility limit in the crystal.

20. The method according to claim 16 wherein the deep level element is vanadium.

21. The method according to claim 16 wherein graphite parts of a sublimation growth furnace are highly purified to reduce the shallow carrier concentration in the silicon carbide crystal growth to at least less than 5·10¹⁶ cm⁻³ and preferably less than 1·10¹⁶ cm⁻³.

22. The method according to claim 16 wherein sublimation growth is carried out to produce single polytype crystals of high purity and a low concentration of deep levels exhibiting a high resistivity of at least 1·10⁶ Ohm-cm, preferably at least 1·10⁸ Ohm-cm, and most preferably at least 1·10⁹ Ohm-cm.

23. The method according to claim 16 wherein substrates fabricated from a crystal exhibit a resistivity that is uniform to at least ±15% over the substrate area.

24. The method according to claim 16 wherein substrates fabricated from a crystal exhibit a capacitance of less than 5 pF/mm² and preferably below 1 pF/mm².

25. The method according to claim 16 wherein substrates fabricated from a crystal exhibit a thermal conductivity greater than 320 W/m-K, and preferably greater than 400 W/m-K.
